(19) United States
(12) Patent Application Publication
(10) Pub. No.: US 2017/0018672 A1
(43) Pub. Date: Jan. 19, 2017

(54) HIGH POWER SOLAR CELL MODULE

(71) Applicant: Win Win Precision Technology Co., Ltd., Hsinchu City (TW)

(72) Inventors: Cheng-Lien Wang, Taoyuan City (TW); Chien-Hsiang Chen, Taoyuan City (TW); Chien-Chun Hsieh, Hualien County (TW)

(21) Appl. No.: 15/064,606

(22) Filed: Mar. 9, 2016

(30) Foreign Application Priority Data
Jul. 16, 2015 (TW) 104123117

(51) Int. Cl. H01L 31/054; H01L 31/0224; H01L 31/05; H01L 31/048

(52) U.S. Cl. CPC H01L 31/0547; H01L 31/048; H01L 31/022458; H01L 31/0508

(57) ABSTRACT

A high power solar cell module including a cover plate, a back plate, a first encapsulant, a second encapsulant, a plurality of P type passivated emitter rear contact solar cells and a plurality of reflective connection ribbons is provided. Each of the P type passivated emitter rear contact solar cells has a light receiving surface and a non-light receiving surface opposite to the light receiving surface. The reflective connection ribbons are located between the first encapsulant and the second encapsulant, and any two adjacent P type passivated emitter rear contact solar cells are connected in series along a first direction by at least four of the reflective connection ribbons. Each of the reflective connection ribbons has a plurality of triangle columnar structures. Each of the triangle columnar structures points to the cover plate and extends along the first direction.

### CROSS-REFERENCE TO RELATED APPLICATION

This application claims the priority benefit of Taiwan application serial no. 104123117, filed on Jul. 16, 2015. The entirety of the above-mentioned patent application is hereby incorporated by reference herein and made a part of this specification.

### BACKGROUND OF THE INVENTION

Field of the Invention

The invention relates to a solar cell module, and particularly relates to a high power solar cell module.

Description of Related Art

Solar cells may convert solar energy into electric energy, and none substance harmful to the environment, such as carbon dioxide or nitride, etc., is produced during a photoelectric conversion process. Therefore, the solar cells have become a very important and popular part on renewable energy research of recent years.

Types of the solar cells include single crystal silicon, poly-crystal silicon, amorphous silicon, thin-film and dye solar cells. The single crystal silicon solar cells include N-type solar cells and P-type solar cells. The N-type solar cells have higher photoelectric conversion efficiency, and a solar cell module composed of 60 pieces of 6-inch N-type solar cells may reach a power above 300 watts. However, the N-type solar cell has a relatively high cost, and has problems of complex manufacturing process and low yield, etc. Compared to the N-type solar cell, the P-type solar cell has relatively low cost, an easier manufacturing process and a relatively high yield. However, the photoelectric conversion efficiency of the P-type solar cell is lower than that of the N-type solar cell, so that an output power of the P-type solar cell is generally lower than an output power of the N-type solar cell. Although some amelioration has been made on the output power of the P-type solar cell according to the existing technique, the amelioration effects still have a room for improvement.

### SUMMARY OF THE INVENTION

The invention is directed to a high power solar cell module, which has a high output power.

The invention provides a high power solar cell module including a cover plate, a back plate, a first encapsulant, a second encapsulant, a plurality of P-type passivated emitter rear contact (PERC) solar cells and a plurality of reflective connection ribbons. The back plate is opposite to the cover plate. The first encapsulant is located between the cover plate and the back plate. The second encapsulant is located between the first encapsulant and the back plate. The P-type PERC solar cells are located between the first encapsulant and the second encapsulant, and each of the P-type PERC solar cells has a light receiving surface and a non-light receiving surface opposite to the light receiving surface. The reflective connection ribbons are located between the first encapsulant and the second encapsulant, and any two adjacent P-type PERC solar cells are connected in series along a first direction by at least four of the reflective connection ribbons. Each of the reflective connection ribbons has a plurality of triangle columnar structures. Each of the triangle columnar structures points the cover plate and extends along the first direction.

In an embodiment of the invention, a surface of the back plate facing the cover plate has a plurality of microstructures. The microstructures reflect a light beam entering the high power solar cell module from the cover plate, and the light beam is subjected to a total inner reflection at an outer surface of the cover plate.

In an embodiment of the invention, a light transmittance of the first encapsulant and the second encapsulant for light beams having a wavelength within a range of 250 nm to 340 nm is higher than 70%.

In an embodiment of the invention, each of the P-type PERC solar cells includes a P-type doped substrate, an N-type doped layer, a first electrode layer, an insulation layer, a second electrode layer and a back electrode layer. The P-type doped substrate has a first surface and a second surface. The first surface is located between the light receiving surface and the non-light receiving surface. The second surface is located between the first surface and the non-light receiving surface. The N-type doped layer is disposed on the first surface. The first electrode layer is disposed on the N-type doped layer and includes four bus electrodes. Each of the reflective connection ribbons is located on one of the bus electrodes. The insulation layer is disposed on the second surface and has a plurality of openings. The back electrode layer is disposed in at least a part of the openings.

In an embodiment of the invention, each of the P-type PERC solar cells further includes an anti-reflection layer. The anti-reflection layer is disposed on the N-type doped layer and located in a region outside the first electrode layer.

In an embodiment of the invention, the back electrode layer is further disposed on the insulation layer.

In an embodiment of the invention, the insulation layer includes an oxide layer, a nitride layer or a stacked layer of the above two layers.

In an embodiment of the invention, a width of each of the reflective connection ribbons is within a range of 0.8 mm to 1.5 mm, and a thickness of each of the reflective connection ribbons is within a range of 0.15 mm to 0.3 mm.

In an embodiment of the invention, the reflective connection ribbons are respectively fixed on the P-type PERC solar cells through a thermosetting conductive adhesive layer.

In an embodiment of the invention, each of the reflective connection ribbons further has a reflection layer. The reflection layer is disposed on the triangle columnar structures, and reflectivity of the reflection layer is higher than 95%.

In an embodiment of the invention, a material of the reflection layer includes silver, and a thickness of the reflection layer is within a range of 0.5 μm 10 μm.

According to the above descriptions, since the P-type PERC solar cells adopts a passivated emitter rear contact structure, a photoelectric conversion efficiency of the P-type PERC solar cells is improved, and the amount of the reflective connection ribbons and the design of the triangle columnar structures avail improving a light usage rate. Therefore, the high power solar cell module of the invention has a high output power.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a high power solar cell module according to an embodiment of the invention.

FIG. 2 is a cross-sectional view of a P-type passivated emitter rear contact (PERC) solar cell in FIG. 1.

FIG. 3 is a front view of a P-type PERC solar cell in FIG. 1.

FIG. 4 is a back view of the high power solar cell module in FIG. 1.

FIG. 5 is a partial enlarged view of the P-type PERC solar cell in FIG. 2.

### DESCRIPTION OF EMBODIMENTS

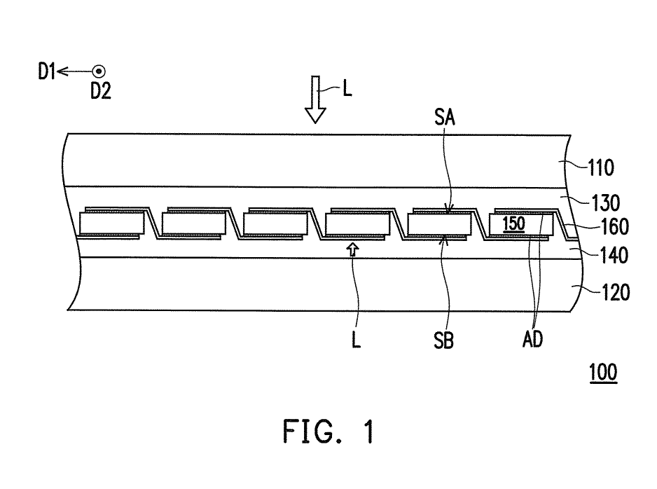

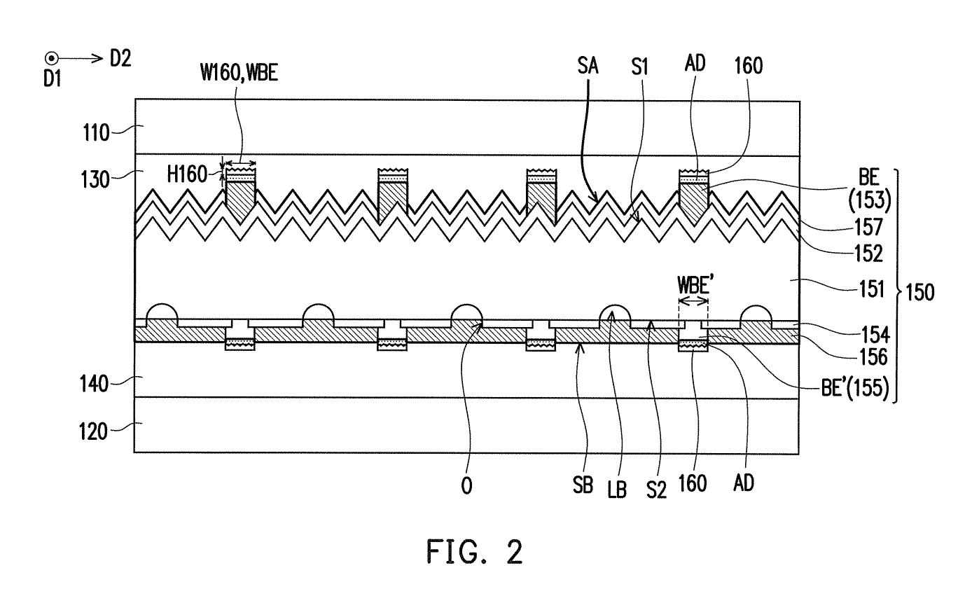

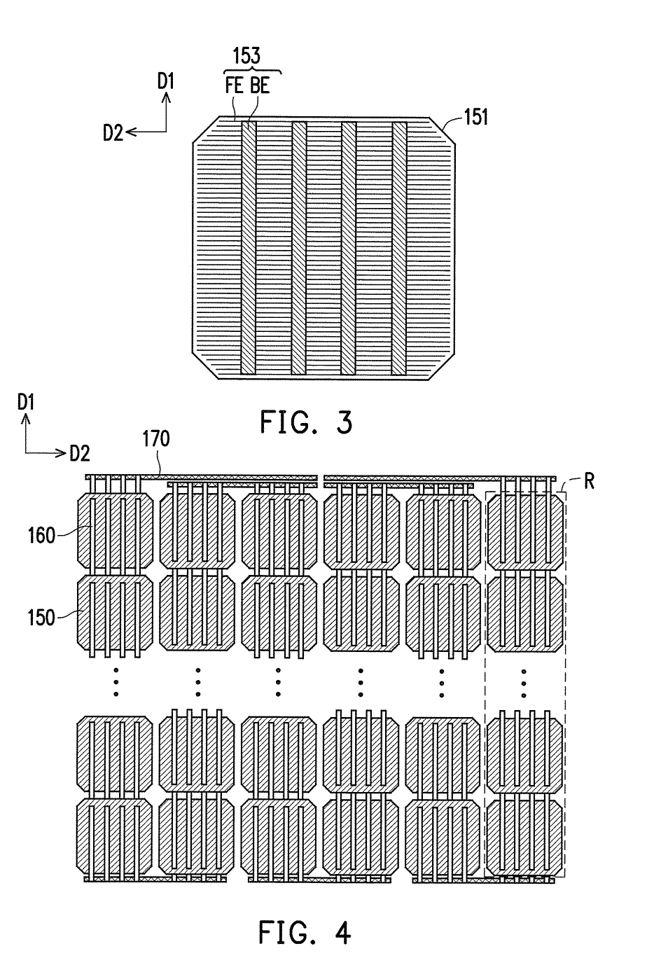

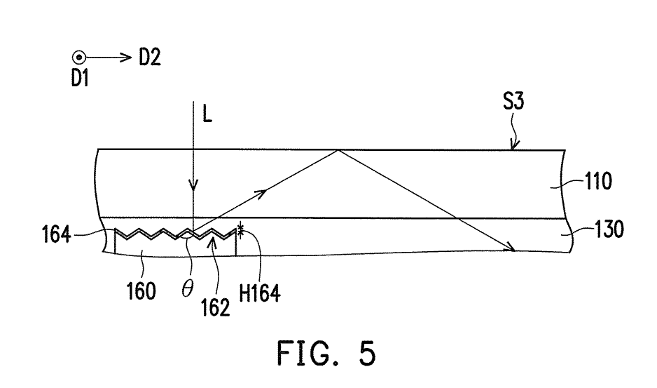

FIG. 1 is a cross-sectional view of a high power solar cell module according to an embodiment of the invention. FIG. 2 is a cross-sectional view of a P-type passivated emitter rear contact (PERC) solar cell in FIG. 1. FIG. 3 is a front view of a P-type PERC solar cell in FIG. 1. FIG. 4 is a back view of the high power solar cell module in FIG. 1, in which a second encapsulant and a back plate in FIG. 1 are omitted. FIG. 5 is a partial enlarged view of the P-type PERC solar cell in FIG. 2. Referring to FIG. 1 to FIG. 5, a high power solar cell module 100 including a cover plate 110, a back plate 120, a first encapsulant 130, a second encapsulant 140, a plurality of P-type PERC solar cells 150 and a plurality of reflective connection ribbons 160.

The cover plate 110 is adapted to protect the P-type PERC solar cells 150 located thereunder, to avoid an external force from impacting and damaging the P-type

PERC solar cells 150. Moreover, a material of the cover plate 110 is a transparent material to avoid influencing the P-type PERC solar cells 150 from absorbing a light beam L coming from external. The transparent material generally refers to a material with a high light transmittance, and is not limited to a material with 100% light transmittance. For example, the cover plate 130 can be a low-iron glass substrate, though the invention is not limited thereto.

The back plate 120 is opposite to the cover plate 110, which is adapted to protect the P-type PERC solar cells 150 located thereon, to avoid an external force from impacting and damaging the P-type PERC solar cells 150. In the present embodiment, the back plate 120 can be a reflective back plate to improve a light usage rate. For example, a surface of the back plate 120 facing the cover plate 110 (i.e. the surface of the back plate 120 that contacts the second encapsulant 140) has a plurality of microstructures (not shown). The microstructures are adapted to reflect the light beam L entering the high power solar cell module 100 from the cover plate 110, such that the light beam L is transmitted to the cover plate 110. The light beam L is subjected to a total inner reflection at a surface (e.g. an outer surface) of the cover plate 110, and is incident to the P-type PERC solar cells 150. In this way, an output power of the high power solar cell module 100 is increased.

The first encapsulant 130 is located between the cover plate 110 and the back plate 120. The second encapsulant 140 is located between the first encapsulant 130 and the back plate 120. Specifically, the first encapsulant 130 and the second encapsulant 140 are respectively located on two opposite surfaces of the P-type PERC solar cells 150 for sealing the P-type PERC solar cells 150. A material of the first encapsulant 130 and the second encapsulant 140 adopts a material suitable for blocking moisture and oxygen in the environment. Moreover, the material of the first encapsulant 130 and the second encapsulant 140 adopts a material with a high light transmittance and pervious to ultraviolet light. In this way, a chance that the light beam L penetrates through the first encapsulant 130 to reach the P-type PERC solar cells 150 is enhanced, and a chance that the light beam L reflected by the back plate 120 penetrates through the second encapsulant 140 to reach the P-type PERC solar cells 150 is enhanced. For example, a light transmittance of the first encapsulant 130 and the second encapsulant 140 for light beams having a wavelength within a range of 250 nm to 340 nm is higher than 70%. Moreover, the material of the first encapsulant 130 and the second encapsulant 140 can be ethylene vinyl acetate (EVA), poly vinyl butyral (PVB), polyolefin, polyurethane, silicone or transparent polymer insulation adhesive.

The P-type PERC solar cells 150 are located between the first encapsulant 130 and the second encapsulant 140, and each of the P-type PERC solar cells 150 has a light receiving surface SA and a non-light receiving surface SB opposite to the light receiving surface SA, and the light receiving surface SA is located between the cover plate 110 and the non-light receiving surface SB.

FIG. 2 illustrates an implementation of the P-type PERC solar cell 150, though the structure of the P-type PERC solar cell 150 is not limited to the implementation shown in FIG. 2. As shown in FIG. 2, each of the P-type PERC solar cells 150 includes a P-type doped substrate 151, an N-type doped layer 152, a first electrode layer 153, an insulation layer 154, a second electrode layer 155 and a back electrode layer 156.

The P-type doped substrate 151 has a first surface S1 and a second surface S2. The first surface S1 is located between the light receiving surface SA and the non-light receiving surface SB. The second surface S2 is located between the first surface Si and the non-light receiving surface SB. At least one of the first surface S1 and the second surface S2 may selectively form a textured surface (shown as a serrated surface in FIG. 2) to increase an absorption rate of the light beam L. In FIG. 2, the first surface S1 is the textured surface, and the second surface S2 is a flat surface, though the invention is not limited thereto. For example, in another embodiment, the first surface S1 and the second surface S2 can all be the textured surface.

The N-type doped layer 152 is disposed on the first surface S1, and the N-type doped layer 152 is, for example, conformal to the first surface S1, i.e. the N-type doped layer 152 rises and falls corresponding to the textured surface.

The first electrode layer 153 is disposed on the N-type doped layer 152. Since the first electrode layer 153 is located at a side of the P-type PERC solar cell 150 close to the light receiving surface S1, the first electrode layer 153 may have a patterned design to decrease a proportion that the first electrode layer 153 shields the light beam L. FIG. 3 illustrates an implementation of the first electrode layer 153, though the invention is not limited thereto. As shown in FIG. 3, the first electrode layer 153 may include four bus electrodes BE (busbar) extending along a first direction D1 and a plurality of finger electrodes FE extending from the bus electrodes BE. The finger electrodes FE, for example, respectively extends along a second direction D2. The first direction D1 is, for example, perpendicular to the second direction D2, though the invention is not limited thereto.

The insulation layer 154 is disposed on the second surface S2 and has a plurality of openings O. The insulation layer 154 may include an oxide layer, a nitride layer or a stacked layer of the above two layers. The aforementioned oxide layer can be an aluminium oxide layer or a silicon oxide layer, and the nitride layer can be a silicon nitride layer, though the invention is not limited thereto.

The second electrode layer 155 is disposed in a part of the openings O, and the back electrode layer 156 is disposed in the other part of the openings O. As shown in FIG. 2, the second electrode layer 155 is, for example, disposed in the openings O corresponding to the bus electrodes BE, where the second electrode layer 155 may have a plurality of bus electrodes BE′, and the bus electrodes BE′ and the bus electrode BE may have a similar pattern design, though the invention is not limited thereto. In the present embodiment, the back electrode layer 156 can be further disposed on the insulation layer 154. By a heating process, the back electrode layer 156 may form local back surface fields (local BSFs) LB on the second surface S2 at places adjacent to the openings O. In this way, carrier collection is enhanced and non-absorbed photons can be retrieved, so as to improve the photoelectric conversion efficiency. In another embodiment, a plurality of recesses can be formed on the second surface S2 at places corresponding to the openings O, and the back electrode layer 156 can be filled in the recesses, which also avails forming the local BSFs.

The P-type PERC solar cell 150 may further include an anti-reflection layer 157. The anti-reflection layer 157 is disposed on the N-type doped layer 152 and located in a region outside the first electrode layer 153 for improving the absorption rate of the light beam L. According to different requirements, the P-type PERC solar cell 150 may further include other film layers, which are not introduced.

The reflective connection ribbons 160 are located between the first encapsulant 130 and the second encapsulant 140, and are adapted to connect the P-type PERC solar cells 150 in series along the first direction D1 to from a plurality of cell strings R arranged along the second direction D2 (shown in FIG. 4). Moreover, as shown in FIG. 2, any two adjacent P-type PERC solar cells 150 are connected in series along the first direction D1 by at least four of the reflective connection ribbons 160. Specifically, a part of each of the reflective connection ribbons 160 is located on one of the bus electrodes BE, and the bus electrodes BE and the reflective connection ribbons 160 present a one-to-one setting relationship. Moreover, the other part of each of the reflective connection ribbons 160 is located on one of the bus electrodes BE′, and the bus electrodes BE′ and the reflective connection ribbons 160 also present a one-to-one setting relationship. In the present embodiment, a width W160 of each of the reflective connection ribbons 160 is within a range of 0.8 mm to 1.5 mm, and a thickness H160 of each of the reflective connection ribbons 160 is within a range of 0.15 mm to 0.3 mm. Widths WBE and WBE′ of the bus electrodes BE and BE′ can be the same to the width W160 of the reflective connection ribbons 160, though the invention is not limited thereto. In another embodiment, the widths WBE and WBE′ of the bus electrodes BE and BE′ can be slightly smaller than the width W160 of the reflective connection ribbons 160.

As shown in FIG. 4, the high power solar cell module 100 may further include a plurality of bus ribbons 170 for connecting the cell strings R in series. According to different requirements, the high power solar cell module 100 may further include other components well known in the field, for example, bypass diodes, junction boxes, etc., which are not introduced.

As shown in FIG. 5, each of the reflective connection ribbons 160 has a plurality of triangle columnar structures 162. Each of the triangle columnar structures 162 points the cover plate 110 and extends along the first direction D1. In the present embodiment, each of the triangle columnar structures 162, for example, includes an isosceles triangle, and a vertex angle θ of each of the triangle columnar structures 162 is, for example, within a range of 60 degrees to 90 degrees, though the invention is not limited thereto.

The vertex angles θ can be designed in collaboration with the amount (4) of the reflective connection ribbons 160 corresponding to each of the P-type PERC solar cells 150, so as to optimize the light usage rate. To be specific, the light beam L irradiating the reflective connection ribbon 160 is reflected by the triangle columnar structures 162 and is sequentially transmitted to the cover plate 110, the outer surface S3 of the cover plate 110 (subjected to the total inner reflection at the outer surface S3) and the P-type PERC solar cells 150, and is absorbed by the P-type PERC solar cells 150, which avails improving the light usage rate. Whether the totally inner reflected light beam L can be transmitted to the P-type PERC solar cell 150 is related to the amount of the reflective connection ribbons 160 and the design of the vertex angle θ. Therefore, by adjusting the amount of the reflective connection ribbons 160 (e.g. 4 reflective connection ribbons 160) corresponding to each of the P-type PERC solar cells 150 and the design of the triangle columnar structures 162, the light usage rate can be optimized, so as to increase the output power of the high power solar cell module 100.

Regarding the solar cell module composed of 60 pieces of P-type solar cells in the current market, the output power thereof is about 280 watts. However, according to the above design, the output power of the high power solar cell module 100 of the present embodiment may reach 300 watts (the output power is increased by 7.1%) according to an actual measurement, and the current solar cell module of the 60 pieces of P-type solar cells cannot reach such output power.

In order to closely bond the reflective connection ribbons 160 with the P-type PERC solar cells 150, the reflective connection ribbons 160 can be respectively fixed on the P-type PERC solar cells 150 through a thermosetting conductive adhesive layer AD. To be specific, the thermosetting conductive adhesive layer AD is located between the reflective connection ribbons 160 and the bus electrodes BE and between the reflective connection ribbons 160 and the bus electrodes BE′. The thermosetting conductive adhesive layer AD can be any adhesive layer containing conductive particles and adapted to be cured through a heating process. For example, the thermosetting conductive adhesive layer AD can be a conductive paste recorded in Taiwan Patent Publication No. 1284328, though the invention is not limited thereto.

Moreover, each of the reflective connection ribbons 160 may further has a reflection layer 164 to further improve reflectivity of the reflective connection ribbons 160 (since the reflection layer 164 is very thin, it is only illustrated in FIG. 5). The reflection layer 164 is disposed on the triangle columnar structures 162, and reflectivity of the reflection layer 164 is higher than 95%. For example, a material of the reflection layer 164 include silver, and a thickness H164 of the reflection layer 164 is, for example, within a range of 0.5 μm to 10 μm.

In summary, since the passivated emitter rear contact structure is help for improving the photoelectric conversion efficiency of the P-type PERC solar cells, and the amount of the reflective connection ribbons and the design of the triangle columnar structures avail improving a light usage rate, the high power solar cell module of the invention has a high output power.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

1. A high power solar cell module, comprising:
a cover plate;
a back plate, opposite to the cover plate;
a first encapsulant, located between the cover plate and the back plate;
a second encapsulant, located between the first encapsulant and the back plate;
a plurality of P-type passivated emitter rear contact solar cells, located between the first encapsulant and the second encapsulant, and each of the P-type passivated emitter rear contact solar cells having a light receiving surface and a non-light receiving surface opposite to the light receiving surface; and
a plurality of reflective connection ribbons, located between the first encapsulant and the second encapsulant, wherein any two adjacent P-type passivated emitter rear contact solar cells are connected in series along a first direction by at least four of the reflective connection ribbons, each of the reflective connection ribbons has a plurality of triangle columnar structures, and each of the triangle columnar structures points to the cover plate and extends along the first direction, wherein the reflective connection ribbons are respectively fixed on the P-type passivated emitter rear contact solar cells through a conductive paste, and the reflective connection ribbons cover an upper surface of each of the reflective connection ribbons such that the entire upper surface of each of the reflective connection ribbons is an uneven surface.

2. The high power solar cell module as claimed in claim 1, wherein a surface of the back plate facing the cover plate has a plurality of microstructures, the microstructures reflect a light beam entering the high power solar cell module from the cover plate, and the light beam is subjected to a total inner reflection at an outer surface of the cover plate.

3. The high power solar cell module as claimed in claim 1, wherein a light transmittance of the first encapsulant and the second encapsulant for light beams having a wavelength within a range of 250 nm to 340 nm is higher than 70%.

4. The high power solar cell module as claimed in claim 1, wherein each of the P-type passivated emitter rear contact solar cells comprises a P-type doped substrate, an N-type doped layer, a first electrode layer, an insulation layer, a second electrode layer and a back electrode layer, the P-type doped substrate has a first surface and a second surface, the first surface is located between the light receiving surface and the non-light receiving surface, the second surface is located between the first surface and the non-light receiving surface, the N-type doped layer is disposed on the first surface, the first electrode layer is disposed on the N-type doped layer and comprises four bus electrodes, each of the reflective connection ribbons is located on one of the bus electrodes, the insulation layer is disposed on the second surface and has a plurality of openings, and the back electrode layer is disposed in at least a part of the openings.

5. The high power solar cell module as claimed in claim 4, wherein each of the P-type passivated emitter rear contact solar cells further comprises an anti-reflection layer, and the anti-reflection layer is disposed on the N-type doped layer and located in a region outside the first electrode layer.

6. The high power solar cell module as claimed in claim 4, wherein the back electrode layer is further disposed on the insulation layer.

7. The high power solar cell module as claimed in claim 4, wherein the insulation layer comprises an oxide layer, a nitride layer or a stacked layer of the above two layers.

8. The high power solar cell module as claimed in claim 1, wherein a width of each of the reflective connection ribbons is within a range of 0.8 mm to 1.5 mm, and a thickness of each of the reflective connection ribbons is within a range of 0.15 mm to 0.3 mm.

9. (canceled)

10. The high power solar cell module as claimed in claim 1, wherein each of the reflective connection ribbons further has a reflection layer, the reflection layer is disposed on the triangle columnar structures, a material of the reflection layer comprises silver, and a thickness of the reflection layer is within a range of 0.5 μm to 10 μm.

11. (canceled)
